(19) United States
(12) Patent Application Publication
(10) Pub. No.: US 2005/0186743 A1
(43) Pub. Date: Aug. 25, 2005

(54) Method for manufacturing semiconductor device

(76) Inventor: Hiroyuki Utsunomiya, Tokyo (JP)

Correspondence Address: WHITHAM, CURTIS & CHRISTOFFERSON, P.C., 11491 SUNSET HILLS ROAD, SUITE 340, RESTON, VA, 20190, US

(21) Appl. No.: 11/061,466

(22) Filed: Feb. 22, 2005

(30) Foreign Application Priority Data
Feb. 20, 2004 (JP) 2004-045120

(51) Int. Cl. H01L 21/8242; H01L 21/336

(52) U.S. Cl. 438/286; 438/239; 438/306

(57) ABSTRACT

Provided is a method of manufacturing a semiconductor device capable avoiding occurrence of resist residue on a gate opening portion when forming the gate opening portion finely for injecting an impurity to form an asymmetric transistor during patterning of a gate electrode. The method of manufacturing the semiconductor device, in a case of manufacturing a DRAM (Dynamic Random Access Memory) with a memory cell transistor made up of the asymmetric transistor, performs separately a first gate electrode patterning process for forming a high concentration N-type diffusion region to be electrically connected to a capacitive element via a capacitive contact connect, and a gate second electrode patterning process for forming a high concentration N-type diffusion region to be electrically connected to a bit line via a bit contact.

### BACKGROUND OF THE INVENTION

1. Field of the Invention

The present invention relates to a method for manufacturing a semiconductor device, and more particularly to the method for manufacturing the semiconductor device, such as a DRAM (Dynamic Random Access Memory) including a plurality of memory cells each made up of an asymmetrical transistor.

The present application claims priority of Japanese Patent Application No. 2004-045120 filed on Feb. 20, 2004, which is hereby incorporated by reference.

2. Description of the Related Art

An LSI (Large Scale Integrated Circuit), known as a typical semiconductor device, is broadly classified into two kinds of devices, a memory device and a logic device. In a recent semiconductor manufacturing technology, improvement of a memory device manufacturing technology is especially remarkable. This memory device is further classified into two kinds of memory devices, a volatile memory device and a nonvolatile memory device and the volatile memory device is still further classified into two kinds of RAM devices, an SRAM (Static Random Access Memory) and a DRAM (Dynamic Random Access Memory). Almost of all these semiconductor memory devices are made up of a MOS (Metal Oxide Semiconductor)-type transistor allowing a deeper density (high-integration). Especially, the DRAM has a great advantage compared with the SRAM in a high integration effecting reduction in cost, mentioned above, and therefore has a wide use application to various kinds of information storage devices such as information devices or a like.

The DRAM makes up one memory cell with a memory cell selecting transistor (hereafter be referred to as a memory cell transistor) made up of the MOS-type transistor that works a switching operation and a capacitor (a capacitive element) connected to the memory cell transistor, and stores information by a presence or a absence of a charge of the capacitive element. Here, as the integration degree of the DRAM is heightened, dimensions of each memory cell are made smaller; therefore, there is a tendency that a device size is also made smaller. Regarding wirings for connecting between a CPU (Central Processing Unit) and semiconductor regions each making up the memory cell, it is difficult to achieve a high wiring density matched to a high integration by the wirings formed in only a planar direction on a semiconductor substrate.

For this reason, a three-dimension structure having upper wirings and lower wirings formed via each of interlayer dielectrics (interlayer insulating films) on the semiconductor substrate, the so-called multi-layer interconnection has recently a wide use application, thus capable of ensuring the high wiring density. As for these DRAMs, wiring having a low resistance is desirable to be formed because the resistance has a great influence on characteristics of the operation speed or a like.

The DRAM including a plurality of memory cells of the composition mentioned above is disclosed, for example, in Japanese Patent Application Laid-open Nos. 2000-174232 and 2003-31690. As for a DRAM (not labeled or numbered), as shown in FIG. 19, a device isolation insulacrIng layer 52 (field dielectric) which is made up of silicon dioxide (SiO₂), for example, and insulates between devices, is selectively buried and is formed in, for example, a P (positive)-type silicon substrate 51, by using a well-known STI (Shallow Trench Isolation) method or a like. Then on an element forming region surrounded by the device isolation insulating layer 52, a gate electrode 54 (word line) made of, for example, a poly-silicon, is formed through a gate insulating film 53 made of, for example, a silicon dioxide and then a surface of the gate electrode 54 is covered by a first interlayer dielectric 55 made of, for example, a silicon dioxide. And on a surface of the P-type silicon substrate 51 surrounding the gate electrode 54, N-type diffusion regions 56 and 57 serving as a source region or a drain region are selectively formed. Then a memory cell transistor 58, constructed by the MOS-type transistor, is made up of the gate electrode 54 through the gate insulating film 53, the N-type diffusion region 56, and the N-type diffusion region 57.

A first opening portion 59 is formed through the gate insulating film 53, the gate electrode 54, and the first interlayer dielectric 55, formed and stacked in layers on the N-type diffusion region 56 on a capacitive element side, and then a capacitive contact 60 is buried and formed in the first opening portion 59. On the capacitive contact 60, is a capacitive lower electrode 61 formed, furthermore, on the capacitive lower electrode 61, a capacitive upper electrode 63 is formed through a capacitive dielectric 62. Then the capacitive element 64 is made up of the capacitive lower electrode 61, the capacitive dielectric 62, and the capacitive upper electrode 63 and then the capacitive element 64 is electrically connected to the N-type diffusion region 56 of the memory cell transistor 58 through the capacitive contact 60.

A surface of the first interlayer dielectric 55 including the capacitive element 64 is covered with a second interlayer dielectric 65 made of, for example, a silicon dioxide. Furthermore, a second opening portion 66 is formed through the gate insulating film 53, the gate electrode 54, and the first interlayer dielectric 55, formed respectively and stacked in layers on the N-type diffusion region 57 to be electrically connected to a bit contact 67 on a bit line side, and the second interlayer dielectric 65, and then a bit contact 67 is buried and formed in the second opening portion 66. A bit line 68 is formed on the bit contact 67 and a protective insulation layer 69 made of, for example, a silicon dioxide is formed on the second interlayer dielectric 65 including the bit line 68. Therefore one memory cell 70 is made up of the memory cell transistor 58 and the capacitive element 64 connected to the memory cell transistor 58. Then, the DRAM is configured of the plurality of memory cells 70 arranged in a matrix state. Still more, the memory cell described in Japanese Patent Application Laid-open Nos. 2000-174232 and 2003-31690 has a structure in which a capacitive element is arranged on an over place of a bit line, such as so-called COB (Capacitive element Over Bit line) structure, meanwhile, the memory cell 70, shown in FIG. 19, has a so-called CUB (Capacitive element Under Bit line) structure in which the capacitive element 64 is arranged on an under place of the bit line 68, even though both DRAMs have the same operation.

In the DRAM mentioned above, to operate the memory cell transistor 70 with high reliability, it is desirable to reduce a current leakage by relaxing an electric field on one side of the gate electrode 54, that is, on the capacitive element 64 side, and to increase operation speed by achieving low resistance on another side of the gate electrode 54, that is, on the bit line 68 side. Concretely, the memory cell transistor 70 is made in a way that the N-type diffusion region 56 connected to the capacitive element 64 through the capacitive contact 60 and the N-type diffusion region 57 connected to the bit line 68 through the bit contact 67 are formed differently in specifications (diffusion depth, impurity concentration distribution, or a like), that is, it is necessary that the memory cell 70 is made up of an asymmetrical transistor. Therefore as shown in FIG. 20, for example, only the N-type diffusion region 57 connected to the bit contact 67 is made up of a first N⁺-type (to be called a high concentration N-type) diffusion region 57A and a second high concentration N-type diffusion region 57B so as to lower resistance on a region connected to the bit line 68.

Next, referring to FIGS. 21 to 25, a method of manufacturing a conventional semiconductor device (DRAM) in which the memory cell transistor 70 is made up of an asymmetrical transistor, as mentioned above, will be described in order of processes. Still each of FIGS. 22A, 23A, 24A, and 25A is respective cross-sectional view or FIGS. 22B, 23B, 24B, and 25B taken along a line A-A.

At first, as shown in FIG. 21, the device isolation insulating layer 52, which is made up of the silicon dioxide, for example, and insulates between devices, is selectively buried and formed in, for example, the P-type silicon substrate 51, by using the well-known STI method or the like. Next, after forming the gate insulating film 53 made of a silicon dioxide on a surface of P-type silicon substrate 51 by a thermal oxidation method, a gate conductive film 54A made of a poly-silicon and the first interlayer dielectric 55 made of a silicon dioxide are formed sequentially by a CVD (Chemical Vapor Deposition) method or a like. Next, as shown in FIGS. 22A and 22B, after coating a photo-resist (not shown) on the upper surface of the work, a first photo-resist film 71 having a preferable pattern is obtained by being exposed and developed in sequence. That is, the first photo-resist film 71 having the desired pattern with a depth H1 is formed in such a manner to remove its photo-resist parts corresponding to regions (not shown) where the N-type diffusion regions 56 and 57 are to be formed. Here, as mentioned above, the N-type diffusion region 56 is formed to contact the capacitive contact 60 on a capacitive element side and the N-type diffusion region 57 is formed to contact the bit contact 67 on a bit line side (see FIG. 20).

Next, as shown in FIGS. 23A and 23B, using the first photo-resist film 71 as a mask the first interlayer dielectric 55, the gate conductive film 54A, and the gate insulating film 53 are dry etched selectively so as to form the first opening portions 59 (gate opening portions) to expose the regions (not shown), in each of which the N-type diffusion region 56 is to be formed on the capacitive element side, and the second opening portions 66 (gate opening portions) to expose the regions (not shown), in each of which the N-type diffusion region 57 is to be formed on the bit line side at a same time. As a result, the gate insulating film 54A is patterned such that the gate electrode 54 is formed. Next, using the first photo-resist film 71 as a mask, ions of an N-type impurity such as Phosphorus (P), Arsenic (As), or a like are injected into the p-type silicon substrate 51 through the first opening portion 59 and the second opening portion 66 so that the high concentration N-type diffusion region 56 and the first high concentration N-type diffusion region 57A are obtained at same time.

Next, after removing the first photo-resist film 71, as shown in FIGS. 24A and 24B, photo-resist (not shown) is coated newly on the upper the surface of the work, after this, exposing and developing are performed, and then, the second photo-resist film 72 having a desirable pattern with a depth H2 is formed newly so as to form the second opening portion 66 again to expose the first high concentration N-type diffusion region 57A on the bit line side. Next, using the second photo-resist film 72 as a mask, ions such like Phosphorus (P), Arsenic (As), or a like are injected into the p-type silicon substrate 51 through the second opening portion 66 and the second high concentration N-type diffusion region 57B is formed to be overlaid on the first high concentration N-type diffusion region 57A, as a result, the N-type diffusion region 57 is completed. Continuously, as shown in FIGS. 25A and 25B the second photo-resist film 72 is removed. Further continuously after forming the capacitive contact 60 (in FIG. 20) on the first opening portion 59, the capacitive element 64 (in FIG. 20) is formed in such a manner to be connected to the capacitive contact 60. Next, after forming the second interlayer dielectric 65 on all surface, the bit contact 67 is formed to make the first interlayer dielectric 55, the second interlayer dielectric 65, in such a manner to be connected to the N-type diffusion region 57. Furthermore, the bit line 68 and the protective insulation layer 69 are formed sequentially so that the memory cell 70 is completed as shown in FIG. 20.

On the other hand in the conventional method of manufacturing the memory cell 70, since as the integration degree of the memory cell 70 is heightened, dimensions of each memory cell 70 are becoming smaller, so that there occurs a problem or resist residue on the gate opening portion (the first and second opening portions 59 and 66) is easy to occur, at a time of forming a gate electrode pattern, when forming the gate opening portion (the first and second opening portions 59 and 66) finely for the impurity injection to form the asymmetric transistor (the memory cell transistor 58).

That is, as for the conventional method of manufacturing the memory cell 70, in processes shown in FIGS. 24A and 24B, when the second photo-resist film 72 is formed newly for forming the second opening portion 66, that is, the gate opening portion (the first and second opening portions 59 and 66) to expose the first high concentration N-type diffusion region 57A connected to the bit line 68 to form the asymmetric transistor (the memory cell transistor 58), again. In this case, a depth size H2 of the second photo-resist film 72 has to be made larger than the depth size H1 of the first photo-resist film 71 formed in advance (H2>H1). Therefore, residues 72′ of a second photo-resist film 72′ is prone to remain left on a vicinity of a bottom of the second opening portion 66. As a result, after that, when using the second photo-resist film 72 as a mask, when ions such like Phosphorus (P), Arsenic (As), or a like are injected into the p-type silicon substrate 51 through the second opening portion 66, not only the second photo-resist film 72, but also the second photo-resist film 72′ work as am ask. This leads the second high concentration N-type diffusion region 57B to be not formed normally. Therefore, since the source region and the drain region are not formed normally, a difference of the threshold of the MOS-type transistor (the memory cell transistor 58) to be manufactured becomes larger. This causes a decrease in the yield, and as a result increases production costs.

### SUMMARY OF THE INVENTION

In view of the above, it is an object of the present invention to provide a method of manufacturing a semiconductor so as to avoid occurrence of resist residue on a gate opening portion when forming the gate opening portion finely for injecting an impurity to form an asymmetric transistor during a process of patterning a gate electrode.

According to a first aspect of the present invention, there is provided a method of manufacturing a semiconductor which includes a first conductive-type of a semiconductor layer, a gate electrode formed through a gate insulating film on the semiconductor layer, a first semiconductor region being a second conductive-type and formed in the semiconductor layer at one side of the gate electrode, a capacitive element connected to the first semiconductor region, a second semiconductor region being the second conductive-type and formed in the semiconductor layer at another side of the gate electrode, a bit line connected to the second semiconductor region,

the method including a step of forming respectively the first semiconductor region and the second semiconductor region formed at a period of time during performing a gate electrode patterning process for patterning and forming the gate electrode,

wherein the gate electrode patterning process further includes;

a first stage of the gate electrode patterning process forming the first semiconductor region together with a first stage of gate electrode pattern; and

a second stage of the gate electrode patterning process forming the second semiconductor region together with a first stage of gate electrode pattern.

According to a second aspect of the present invention, there is provided a method of manufacturing a semiconductor which includes a first conductive-type of a semiconductor layers a gate electrode formed through a gate insulating film on the semiconductor layer, a first semiconductor region being a second conductive-type and formed in the semiconductor layer at one side of the gate electrode, a capacitive element connected to the first semiconductor region, a second semiconductor region being the second conductive-type and formed in the semiconductor layer at another side of the gate electrode, a bit line connected to the second semiconductor region,

the method including steps of forming a trench in the semiconductor layer in such a manner that the trench is located at an approximately central position of a region where the bit line is to be formed; and then forming respectively the first semiconductor region and the second semiconductor region formed at a period of time during performing a gate electrode patterning process for patterning and forming the gate electrode,

wherein the gate electrode patterning process further includes:

a first stage of the gate electrode patterning process forming the first semiconductor region together with a first stage of gate electrode pattern; and

a second stage of the gate electrode patterning process forming the second semiconductor region together with a first stage of gate electrode pattern.

In the foregoing first and second aspects, a preferable mode is one that, wherein the first stage of the gate electrode patterning process i followed by the second stage of the second gate electrode patterning process whereby the gate electrode is finally formed.

Another preferable mode is one wherein the second stage of the gate electrode patterning process is followed by the first stage of the second gate electrode patterning process whereby the gate electrode is finally formed.

An additional preferable made is one wherein the first semiconductor region is formed so as to De greater than the second semiconductor region in depth.

Still additional preferable mode is one wherein the second semiconductor region is formed so as to have higher impurity concentration than the first semiconductor region.

With the above configurations, it is capable of preventing resist residue from remaining left in a gate opening portion when forming the gate opening portion finely For injecting an impurity to form an asymmetric transistor during a period of patterning a gate electrode.

### BRIEF DESCRIPTION OF THE DRAWINGS

The above and other objects, advantages, and features of the present invention will be more apparent from the following description taken in conjunction with the accompanying drawings in which:

FIG. 1 is a process diagram for showing a method of manufacturing a semiconductor device in order of processes according to a first embodiment of the present invention;

FIGS. 2A and 2B are process diagrams and showing the method of manufacturing the semiconductor device in order of processes according to the first embodiment of the present invention and FIG. 2A is cross-sectional view of FIG. 2B taken along a line A-A;

FIGS. 3A and 3B are process diagrams showing the method of manufacturing the semiconductor device in order of processes according to the first embodiment of the present invention and FIG. 3A is cross-sectional view of FIG. 3B taken along a line A-A;

FIGS. 4A and 4B are process diagrams showing the method of manufacturing the semiconductor device in order of processes according to the first embodiment of the present invention and FIG. 4A is cross-sectional view of FIG. 4B taken along a line A-A;

FIGS. 5A and 5B are process diagrams showing the method of manufacturing the semiconductor device in order of processes according to the first embodiment of the present invention and FIG. 5A is cross-sectional view of FIG. 5B taken along a line A-A;

FIGS. 6A and B are process diagrams showing the method of manufacturing the semiconductor device in order of processes according to the first embodiment of the present invention and FIG. 6A is cross-sectional view or FIG. 6B taken along a line A-A;

FIG. 7 is a process diagram for showing the method of manufacturing the semiconductor device in order of processes according to the first embodiment of the present invention;

FIG. 8 is a process diagram for showing the method of manufacturing the semiconductor device in order of processes according to the first embodiment of the present invention;

FIG. 9 is a process diagram for showing a main process of a method of manufacturing a semiconductor device according to a second embodiment of the present invention;

FIG. 10 is a process diagram for showing the main process of the method of manufacturing the semiconductor device according to the second embodiment of the present invention;

FIG. 11 is a process diagram for showing the main process of the method of manufacturing the semiconductor device according to the second embodiment of the present invention:

FIG. 12 is a process diagram for showing the main process of the method of manufacturing the semiconductor device according to the second embodiment of the present invention;

FIG. 13 is a process diagram for showing a main process of a method of manufacturing a semiconductor device according to a third embodiment of the present invention;

FIG. 14 is a process diagram for showing the main process of the method of manufacturing the semiconductor device according to the third embodiment of the present invention;

FIG. 15 is a process diagram for showing the main process of the method of manufacturing the semiconductor device according to the third embodiment of the present invention;

FIG. 16 is a process diagram for showing the main process of the method of manufacturing the semiconductor device according to the third embodiment of the present invention;

FIG. 17 is a process diagram for showing the main process of the method of manufacturing the semiconductor device according to the third embodiment of the present invention;

FIG. 18 is a process diagram for showing the main process of the method of manufacturing the semiconductor device according to the third embodiment of the present invention;

FIG. 19 is a cross-sectional view showing a conventional semiconductor device;

FIG. 20 is a cross-sectional view for showing another conventional semiconductor device;

FIG. 21 is a process diagram showing a method of manufacturing the conventional semiconductor device in order of processes;

FIGS. 22A and 22 are process diagrams showing the method of manufacturing the conventional semiconductor device in order of processes and FIG. 22A is cross-sectional view of FIG. 22B taken along a line A-A;

FIGS. 23A and 23B are process diagrams showing the method of manufacturing the conventional semiconductor device in order of processes and FIG. 23A is cross-sectional view of FIG. 23B taken along a line A-A;

FIGS. 24A and 24B are process diagrams showing the method of manufacturing the conventional semiconductor device in order of processes and FIG. 24A is cross-sectional view of FIG. 24B taken along a line A-A; and

FIGS. 25A and 25B are process diagrams showing the method of manufacturing the conventional semiconductor device in order of processes and FIG. 25A is cross-sectional view of FIG. 25B taken along a line A-A.

### DETAILED DESCRIPTION OF THE PREFERRED EMBODIMENTS

Best modes of carrying out the present invention will be described in further detail using various embodiments with reference to the accompanying drawings.

### First Embodiment

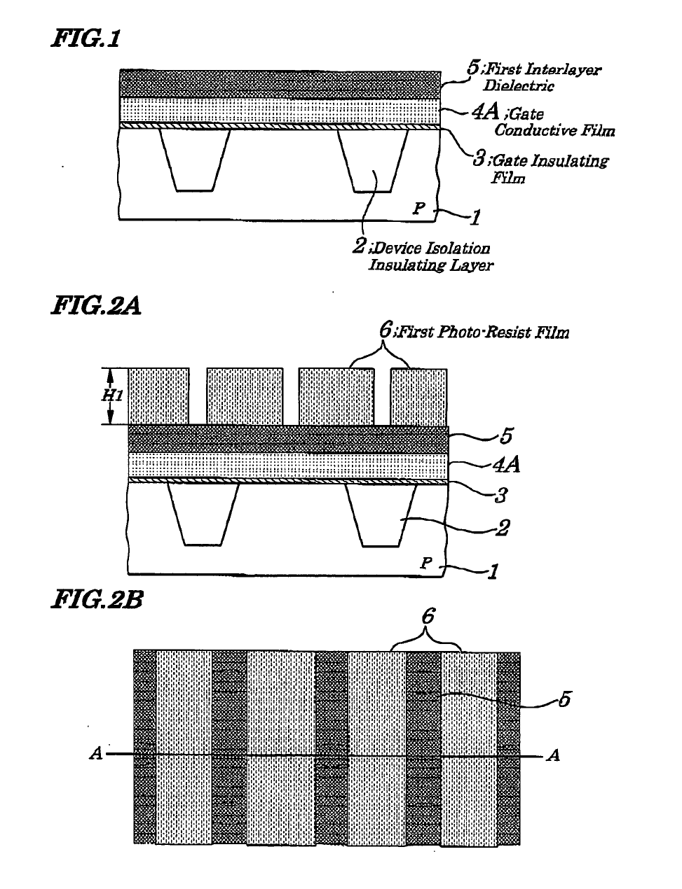

FIGS. 1 to 8 are process diagrams for showing a method or manufacturing a semiconductor device in order or processes according to a first embodiment of the present invention. The method of manufacturing the semiconductor device in order of processes will be described referring to FIGS. 1 to 8 as follows. Furthermore in FIGS. 2A to 6A, FIG. A is a cross-sectional view of FIGS. 2B to 6B, respectively taken along a line A-A.

At first, as shown in FIG. 1, a device isolation insulating layer 2, which is made up of a silicon dioxide (SiO₂), for example, and insulates between devices, is selectively buried and formed in, for example, a P (positive)-type silicon semiconductor substrate 1, by using a well-known STI (Shallow Trench Isolation) method. Next, after forming a gate insulating film 3 made of a silicon dioxide with a thickness of 2˜10 nm by a thermal oxidation method, a gate conductive film 4A made of a poly-silicon with a thickness of 0.2˜1.0 μm and a first interlayer dielectric 5 made of a silicon dioxide with a thickness of 0.3˜1.2 μm are formed by a CVD (Chemical Vapor Deposition) method or a like sequentially.

Next, as shown in FIGS. 2A and 2B, after applying a photo-resist on the upper surface of the first interlayer dielectric 5, exposing and developing are carried out sequentially, to form a first photo-resist film 6 having a desired pattern with a depth H1 to expose desired parts or the first interlayer dielectric 5 and to expose regions, in each of which a diffusion region is to be formed and to be electrically connected to a bit contact (not shown) on a bit line side.

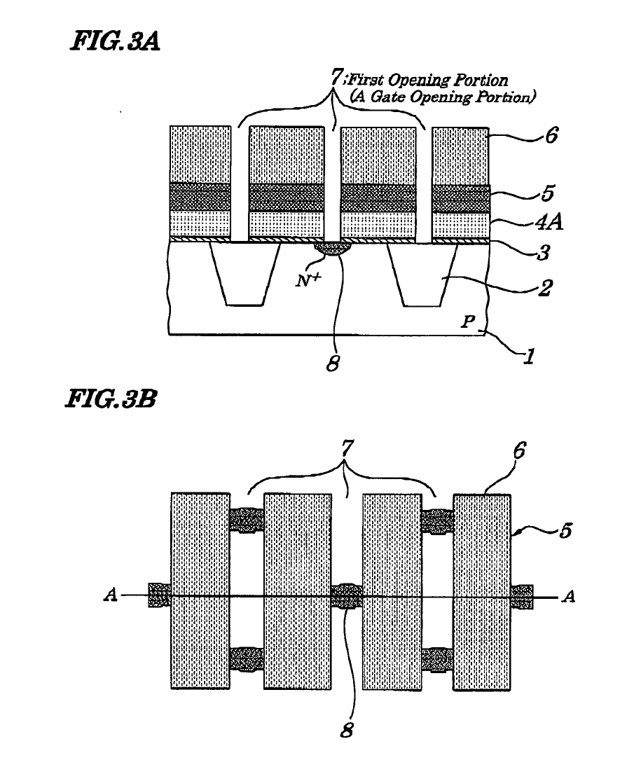

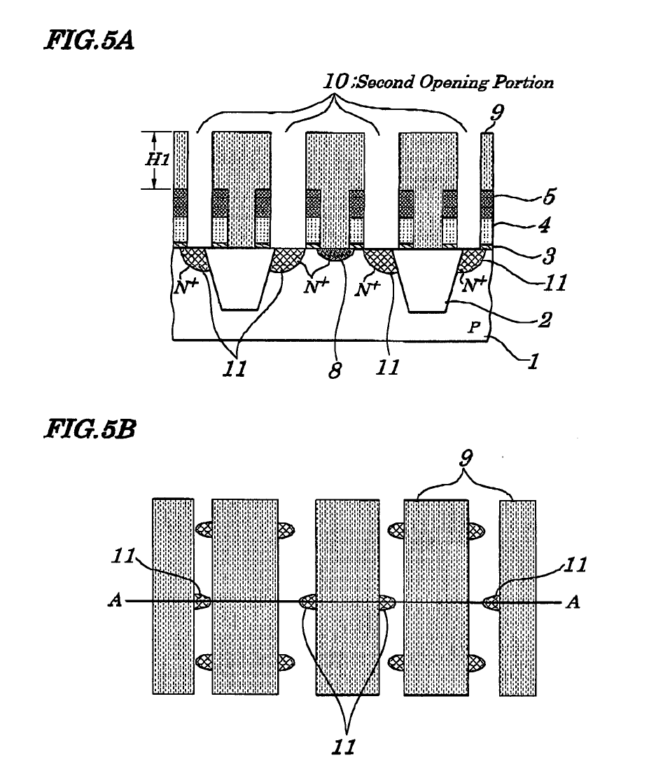

Next, as shown in FIGS. 3A and 3B, the first interlayer dielectric 5, the gate conductive film 4A, and the gate insulating film 3 are selectively etched using the first photo-resist film 6 as a mask to form first opening portions 7 (gate opening portions) to expose regions, in each of which an N-type diffusion region is to be formed and to be connected to the bit contact (not shown) on the bit line side, that is, to be connected the bit line via the bit contact. Next, using the first photo-resist film 6 as a mask an N-type impurity such as Phosphorus (P), Arsenic (As) , or a like is injected into the P-type silicon semiconductor substrate 1 to have a dosage of 1×10¹²˜133 10¹⁴ ions/cm² through the first opening portion 7 and a high concentration N-type diffusion region 8 is formed with an annealing treatment. The high concentration N-type diffusion region 8 is formed in a manner to satisfy a low resistance as a required condition of the bit line (not shown), because the high concentration N-type diffusion region 8 serves as the diffusion region to be electrically connected to the bit contact (not shown), which is to be formed in a subsequent process. For this purpose, it is preferable to form the high concentration N-type diffusion region 8 to be relatively shallow, at least to be deeper than a high concentration N-type diffusion region 11 (see FIGS. 5A and 5B) which is formed on a capacitive element side, as described later.

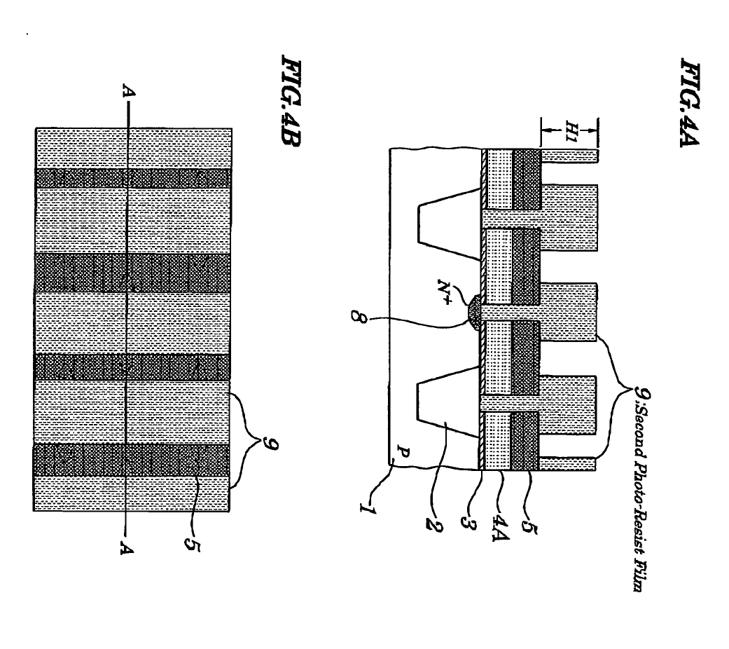

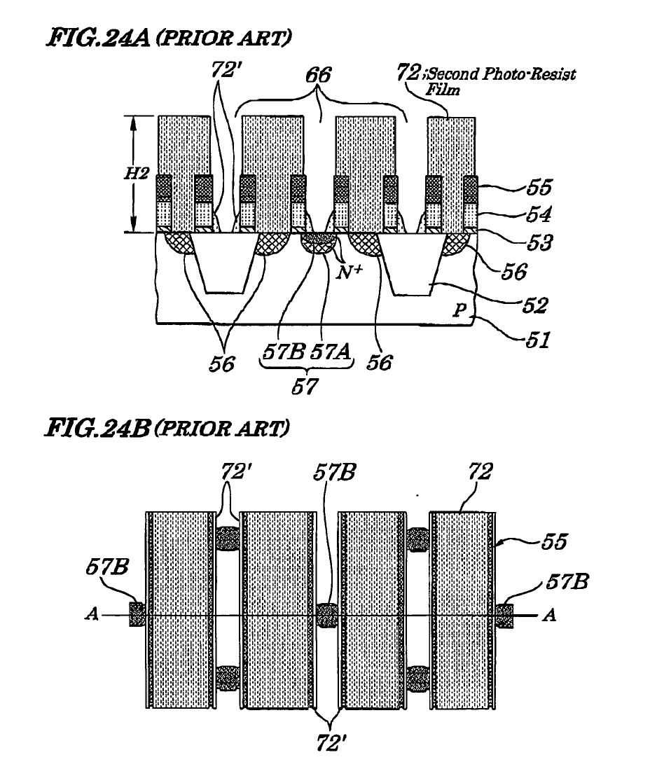

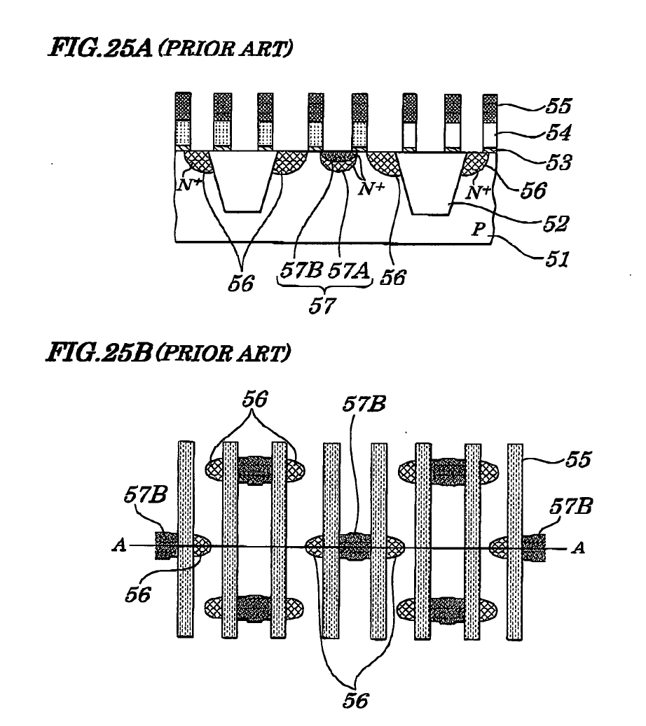

Next, after removing the first photo-resist film 6, as shown in FIGS. 4A and 4B, a photo-resist is applied on all surface, and exposing and developing are carried out to form a second photo-resist film 9 having a desired pattern with the depth of H1 to expose the desired regions of the first interlayer dielectric 5, in each of which a diffusion region is to be formed and to be electrically connected to a capacitive contact (not shown) on the capacitive element side, that is, to be connected to the capacitive element via a capacitive contact In the embodiment, it is a feature that the second photo-resist film 9, which is used to form the diffusion region on the capacitive element side, is set to the depth H1, the same as that of the first photo-resist film 6 which is used to form the diffusion region on the bit line side. As described above forming the first photo-resist film 6 and the second photo-resist film 9 to have same depth H1 as each other avoids to leave the second photo-resist film 9 on a second opening portion 10 (a gate opening portion) (see FIG. 5A) unlike in a conventional process shown In FIGS. 24A and 24B when the second opening portion 10 (see FIG. 5A) is formed after forming the second photo-resist film 9.

Next, as shown in FIGS. 4A and 4B, and FIGS. 5A and 5B, the first interlayer dielectric 5, the remaining gate conductive film 4A, and the gate insulating film 3 are selectively etched using the second photo-resist film 9 as a mask to form the second opening portions 10 (the gate opening portions) to expose the desired regions, in each of which the N-type diffusion region is to be formed and to be connected to the capacitive contact (not shown) on the capacitive element side. This allows the remaining gate conductive film 4A patterned such that the gate electrode 4 is formed. Next, using the second photo-resist film 9 as a mask, the N-type impurity such as Phosphorus (P), Arsenic (As), or a like is injected into the P-type silicon semiconductor substrate 1 to have a dosage of 1×10¹²˜1×10¹⁴ ions/cm² through the second opening portion 10 and next the high concentration N-type diffusion 11 is formed by an annealing treatment. The high concentration N-type diffusion region 11 is formed in a manner to achieve a relaxation of an electric field as a required condition of the capacitive element (not shown), because the high concentration N-type diffusion region 11 serves as the diffusion region to be electrically connected to the capacitive contact, which will be formed in a subsequent process. For this purpose it is preferable to form the high concentration N-type diffusion region 11 to be relatively deep, at least to be deeper than the high concentration N-type diffusion region 8 which is formed to be connected to the bit line (not shown) as described later. Furthermore, in a case of forming the high concentration N-type diffusion region 11, the second photo-resist film 9 is completely removed from the second opening portion 10 as described above. Therefore, when the N-type impurity such as Phosphorus (P), Arsenic (As), or a like is injected into the P-type silicon semiconductor substrate 1 through the second opening portion 10 using the second photo-resist film 9 as a mask, only the second photo-resist film 9 acts as a mask so that the high concentration N-type diffusion region 11 is formed normally. Therefore the source region or the drain region is formed normally and then an increase in the yield can be obtained because the difference in the threshold voltage vt of the manufactured MOS-type transistor is suppressed.

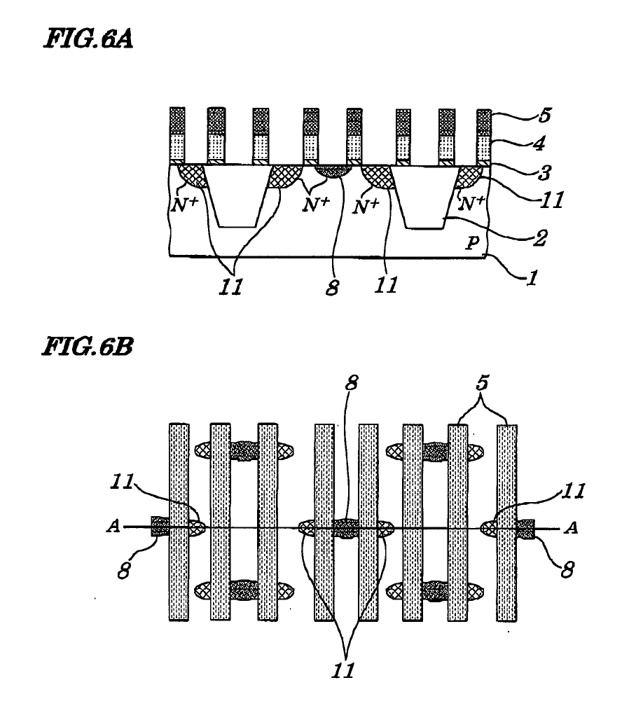

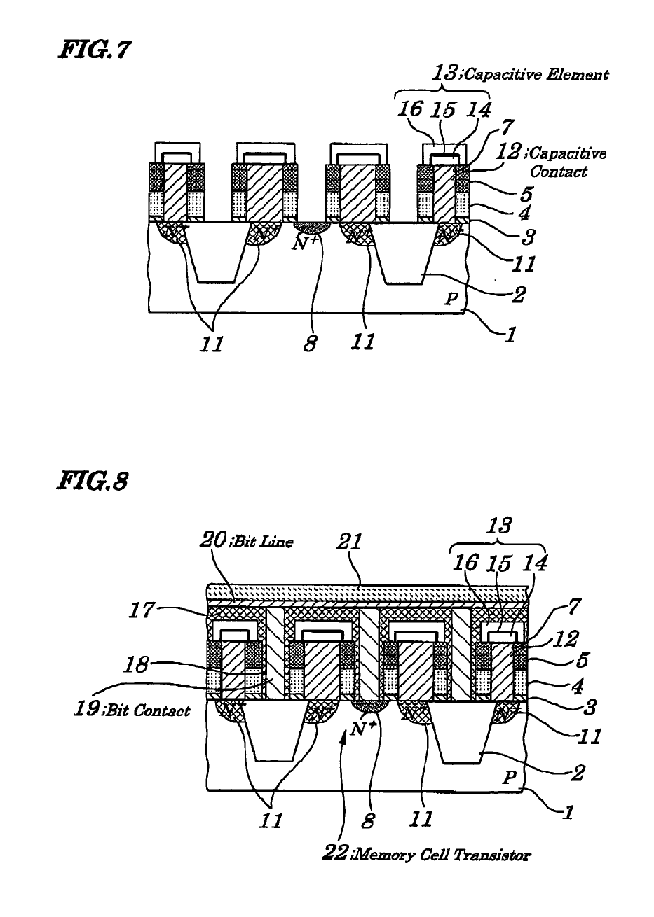

Next, as shown in FIGS. 6A and 6B, after removing the second photo-resist film 9, a capacitive contact 12 (FIG. 7) made of, for example, Tungsten (W) is formed by the CVD method or a like. Next, a capacitive element 13 is formed in such a manner to be connected to the capacitive contact 12. To complete the capacitive element 13, at first a capacitive lower electrode 14 made of, for example, a poly-silicon which is doped by a impurity using the CVD method or a like in such a manner to be connected to the capacitive contact 12, next a capacitive insulating film 15 made of, for example, Silicon Nitride (SiN) is formed by the CVD method or a like, at the end, a capacitive upper electrode 16 made of, for example, Titanium nitride (TiN) is formed.

Next, as shown in FIG. 8, after forming a second interlayer dielectric 17 on the upper surface of the work as shown in FIG. 7, by using the CVD method or a like, a third opening portion 18 is formed in the second interlayer dielectric 17 by the dry etching method to make the high concentration N-type diffusion region exposed. Next, on the third opening portion 18, by the CDV method or a like, a bit contact 19 made of, for example, tungsten (W) is formed. Next, on the second interlayer dielectric 17 a bit line 20 made of, for example, a titanium/tungsten (Ti/W) accumulating film is formed by the CVD method or a like to be connected to the bit contact 19. Next, a protective insulation layer 21 made of a silicon dioxide is formed on the upper surface of the work by using the CVD method or a like. As a result, a memory cell, as similar to that shown in FIG. 20, is completed.

According to the method of manufacturing a semiconductor described above, the first photo-resist film 6 which forms the first opening portion 7 for forming the high concentration N-type diffusion region 8 (the gate opening portion), connected to the bit line 20, and the second photo-resist film 9 which forms the second opening portion 10 (gate opening portion) for forming the high concentration N-type diffusion region 11, connected to the capacitive element 13, are both set to have the same depth H1, that is, the first and second photo-resist films 6 and 9 do not need to be formed thick. As a result, on the first and second opening portions 7 and 10, the first and second photo-resist films 6 and 9 do not remain. So that when the impurity through the first and second opening portions 7 and 10 is injected, using the first and second photo-resist films 6 and 9 as a mask, the first and second photo-resist films 6 and 9 do not remain, so that, each the high concentration N-type diffusion regions 8 and 11 are formed normally. Therefore, the source region (not shown) or the drain region (not shown) is formed normally and then an increase in the yield can be obtained because the difference in the threshold voltage Vt of the manufactured MOS-type transistor is suppressed.

A memory cell transistor 22 or a DRAM, which is manufactured with the method of the semiconductor mentioned above, as shown in FIG. 8, includes the asymmetric transistor (not shown) made up of the high concentration N-type diffusion region 8 connected to the capacitive element 13 and the high concentration N-type diffusion region 11 connected to the bit line 20 whose depth is different each other. Therefore, the high concentration N-type diffusion region 8 connected to the capacitive element 13 is formed relatively thin to have the specification to cover the required condition of the relaxation of the electric field. On the other hand, the high concentration N-type diffusion region 11 connected to the bit line 20 is formed relatively thick to have the specification to cover the required condition of the low resistance.

Therefore, with the above configuration, when the DRAM having the memory cell 22 including the asymmetric transistor is manufactured, a process of a gate electrode patterning to form the high concentration N-type diffusion region 8 connected to the capacitive element 13 and a process of a gate electrode patterning to form the high concentration N-type diffusion region 11 connected to the bit line 20 are separated, so that, in each processes of the gate electrode patterning, forming the first photo-resist film 6 or the second photo-resist film 9 to be thin or thick is not necessary.

In conclusion, during patterning of the gate electrode 4, occurrence of resist residue can be avoided on the gate opening portion (the first and second opening portions 7 and 10) when forming the gate opening portion (the first and second opening portions 7 and 10) finely for injecting the impurity to form the asymmetric transistor (not shown).

### Second Embodiment

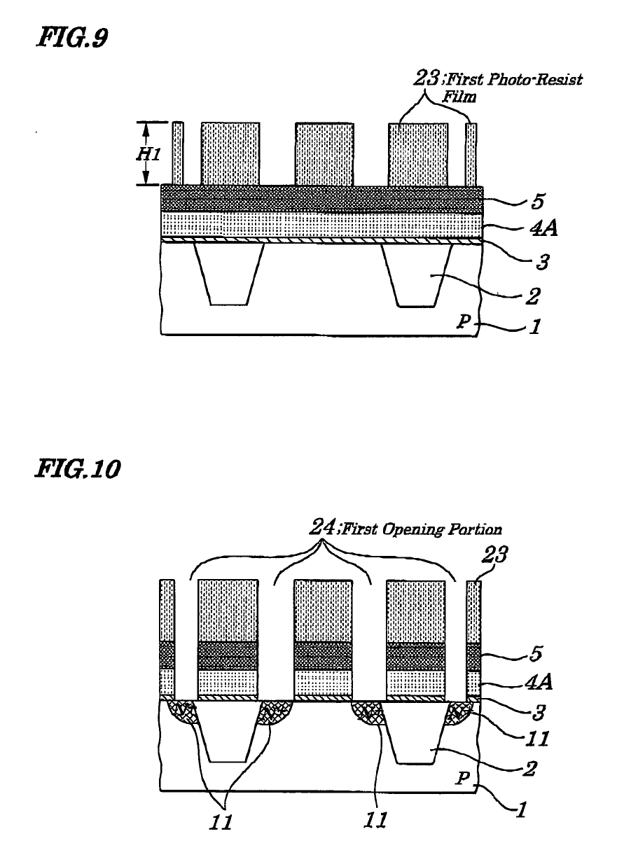

FIGS. 9 to 12 are process diagrams for showing a main process of a method of manufacturing a semiconductor device according to a second embodiment of the present invention. A significant difference between configuration of the method of manufacturing a semiconductor of the first embodiment and the configuration of the method of manufacturing a semiconductor of the second embodiment is that one process of a gate electrode patterning to form a semiconductor region to be connected to a capacitive element via a capacitive contact is carried out in advance of another process of the gate electrode patterning to form a semiconductor region to be connected to a bit line via a bit contact. Hereinafter, the method of manufacturing the semiconductor device according to the second embodiment will be described in order of processes referring to FIGS. 9 to 12.

First, as shown in FIG. 9, a device isolation insulating layer 2, which is made up of a silicon dioxide (SiO₂), for example, and isolates between devices, is selectively buried and formed in, for example, a P (positive)-type semiconductor substrate 1, by using a well-known STI (Shallow Trench Isolation) method. Next, after forming a gate insulating film 3 made of a silicon dioxide with thickness of 2-10 nm on a surface of the gate insulating film 3, a gate conductive film 4A made of a poly-silicon with a thickness of 0.2˜1.0 μm and a first interlayer dielectric 5 made of a silicon dioxide with a thickness of 0.3˜1.2 μm are formed sequentially. Next, after coating a photo-resist on the upper surface of the first interlayer dielectric 5, exposing and developing are carried out to form a first photo-resist film 23 having a desired pattern with a depth H1 to expose the desired regions of the first interlayer dielectric 5, in each of which the diffusion region is to be formed and to be connected to the capacitive contact (not shown) on the capacitive element side.

Next, as shown in FIG. 10, the first interlayer dielectric 5, the gate conductive film 4A, and the gate insulating film 3 are selectively etched using the first photo-resist film 23 as a mask to form a first opening portions 24 (gate opening portions) to expose the desired regions, in each of which an N-type diffusion region is to be formed an to be connected to the capacitive contact (not shown) on the capacitive element side, that is, to be connected to the capacitive element via the capacitive contact. Next, using the first photo-resist film 23 as a mask, an N-type impurity such as Phosphorus (P), Arsenic (As), or a like is injected into the P-type silicon semiconductor substrate 1 to have a dosage of 1×10¹²˜1×10¹⁴ ions/cm² through the first opening portion 24, as a result, and an annealing treatment is conducted, as a result, a high concentration N-type diffusion region 11 is obtained. The high concentration N-type diffusion region 11 is formed in a manner to satisfy a relaxation of an electric field as a required condition of the capacitive element (not shown), because the high concentration N-type diffusion region 11 serves as the diffusion region to be electrically connected to the capacitive element (not shown), which is to be formed in a subsequent process. For this purpose, it is preferable to form the high concentration N-type diffusion region 11 to be relatively deep, at least to be deeper than a high concentration N-type diffusion region 8 (not shown) which is connected to the bit line (not shown) as described later.

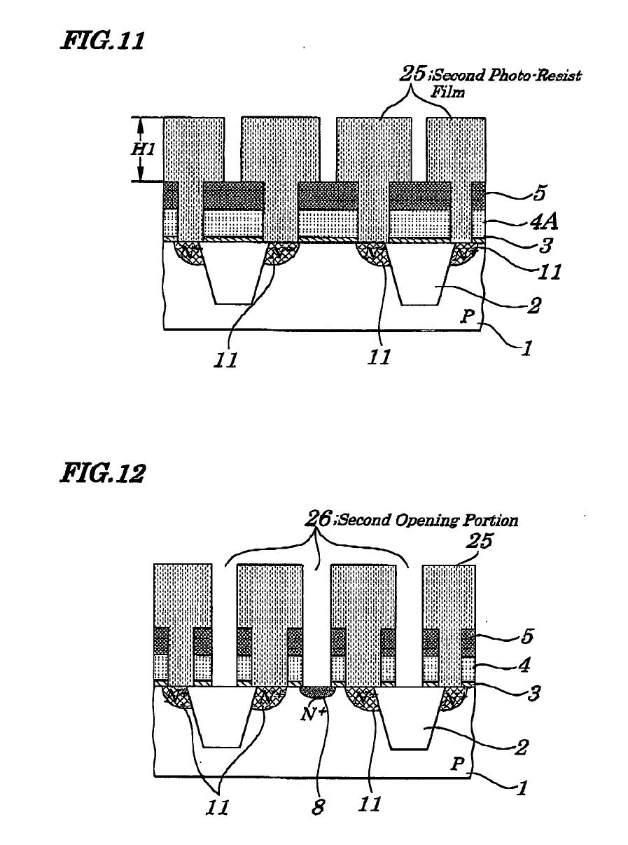

Next, after removing the first photo-resist film 23, as shown in FIG. 11, a photo-resist is coated on the upper surface of the work, and exposing and developing are carried out to form a second photo-resist film 25 having a desired pattern with the depth H1 to expose the desired regions of the first interlayer dielectric 5, in each of which the diffusion region is to be formed and to be connected to the bit contact (not shown) on the bit line side. In the second embodiment, it is a feature that the second photo-resist film 25, which is used to form the diffusion region on the bit line side, is set to depth H1, the same as that of the first photo-resist film 23 which is used to form the diffusion region on the capacitive element side. As described above, since the first photo-resist film 23 and the second photo-resist film 25 are formed to have same depth (thickness) H1, residue of the second photo-resist film 25 is removed completely from a second opening portion 26 (a gate opening portion) (see FIG. 12), unlike in a conventional process shown in FIGS. 24A and 24B when the second opening portion 26 is formed after forming the second photo-resist film 25.

Next, as shown in FIG. 12, the first interlayer dielectric 5, the remaining gate conductive film 4A, and the gate insulating film 3 are selectively etched using the second photo-resist film 25 as a mask so as to form the second opening portions 26 (the gate opening portions) to expose the desired regions, in each of which the N-type diffusion region is to be formed and to be connected to the bit contact (not shown) on the bit line side. This allows the remaining gate conductive film 4A patterned such that the gate electrode 4 is formed. Next, using the second photo-resist film 25 as a mask, the N-type impurity such as phosphorus (P), Arsenic (As), or a like is injected into the P-type silicon semiconductor substrate 1 to have a dosage of 1×10¹²-1×10¹⁴ ions/cm² through the second opening portion 26, and next, a high concentration N-type diffusion region 8 is formed by annealing. The high concentration N-type diffusion region 8 is formed in a manner to satisfy a low resistance as a required condition of the bit line, because the high concentration N-type diffusion region 8 serves as the diffusion region to be electrically connected to the bit contact (not shown), which is to be formed in a subsequent process. For this purpose, it is preferable to form the high concentration N-type diffusion region 8 to be relatively shallow, at least to be more shallow than the high concentration N-type diffusion region 11. Furthermore, in a case of forming the high concentration N-type diffusion region 8, the second photo-resist film 25 does not remain left in the second opening portion 26 as described above. Therefore, when the N-type impurity such as Phosphorus (P), Arsenic (As), or a like is injected into the P-type silicon semiconductor substrate 1 through the second opening portion 26 using the second photo-resist film 25 as a mask, only the second photo-resist film 25 acts as a mask so that the high concentration N-type diffusion region 8 is formed preferably. Therefore, the source region (not shown) or the drain region (not show) is formed preferably and then an increase in the yield can be obtained, thus reducing production costs, because it is possible to reduce the variations in the threshold voltage Vt between the manufactured MOS-type transistors.

Following processes are approximately repeated as described in the processes of the first embodiment shown in FIGS. 6A and 6B. As a result, A DRAM corresponding to FIG. 20 is completed.

Therefore, the embodiment has the almost similar advantages as described in the first embodiment; because only the order of a processes of forming the diffusion region connected to the capacitive element and the diffusion region connected to the bit line is changed.

### Third Embodiment

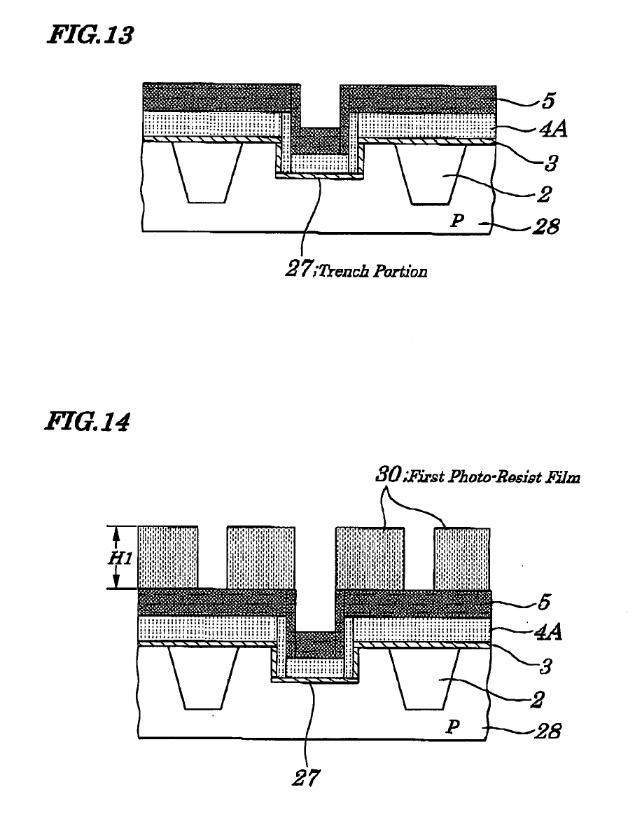

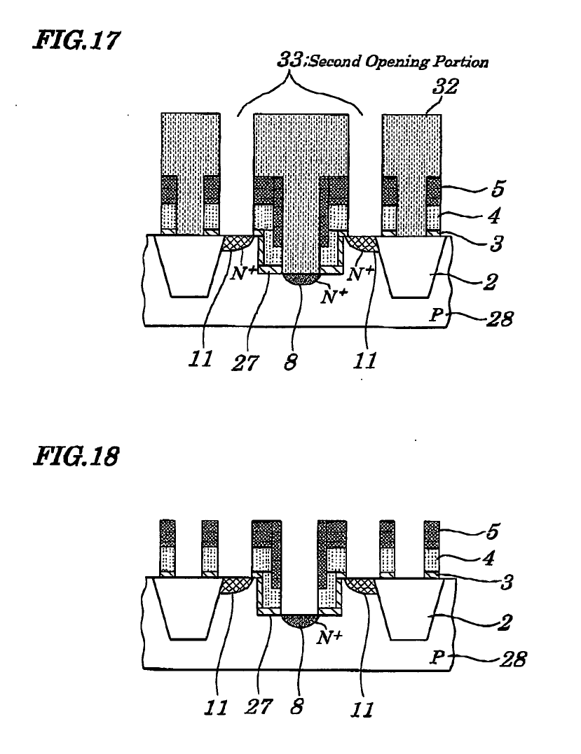

FIGS. 13 to 18 are process diagrams for showing a main process of a method of manufacturing a semiconductor device according to a third embodiment of the present invention. A significant difference of configurations of the method of processing the semiconductor device in the embodiment compared with configurations of the method of processing the semiconductor device described in first and second embodiments is that a memory cell is made up of an asymmetric transistor. Hereafter, the method of manufacturing the semiconductor device according to the third embodiment will be described in order of processes referring to FIGS. 13 to 18.

At first, as shown in FIG. 13, a device isolation insulating layer 2, which is made up of a Silicon dioxide (SiO₂), for example, and insulates between devices, is selectively buried and formed in, for example, a P (positive)-type a semiconductor substrate 28, by using a well-known STX (Shallow Trench Isolation) method. And, a trench portion 27 is formed in an approximately center position. Also, a gate insulating film 3 made of a silicon dioxide with a thickness of 2˜10 nm by a thermal oxidation method, a gate conductive film 4A made of a poly-silicon with a thickness of 0.2˜1.0 μm and a first interlayer dielectric 5 made of a silicon dioxide with the thickness of 0.3˜1.2 μm are formed and stacked in layers in sequence. As a result the P-type silicon substrate 28 is prepared.

Next, as shown in FIG. 14, after coating a photo-resist on the upper surface of the first interlayer dielectric 5, exposing and developing are carried out to form a first photo-resist film 30 having a desired pattern with a depth H1 to expose the desired regions of the first interlayer dielectric 5, in each of which a diffusion region is to be formed and to be connected to a bit contact (not shown) on a bit line side, that is, to be connected to a bit line via a bit contact.

Next, as shown in FIG. 15, the first interlayer dielectric 5, the gate conductive film 4A, and the gate insulating film 3 are selectively etched using the first photo-resist film 30 as a mask to form a first opening portions 31 (gate opening portions) to expose the desired regions, in each of which the N-type diffusion region is to be formed and to be connected to the bit contact (not shown) on the bit line side. Next, using the first photo-resist film 6 as a mask an N-type impurity such as Phosphorus (P), Arsenic (As), or a like is injected into the P-type silicon substrate 28 to have a dosage of 1×10¹²˜1×10¹⁴ ions/cm² through the first opening portion 31 and a high concentration N-type diffusion region 8 is formed with annealing. The high concentration N-type diffusion region 8 is formed in a manner to satisfy a low resistance as a required condition of the bit line because the high concentration N-type diffusion region 8 serves as the diffusion region to be electrically connected to the bit contact (not shown), which is to be formed in a subsequent process. For this purpose, it is preferable to form the high concentration N-type diffusion region B to be relatively shallow, at least to be deeper than a high concentration N-type diffusion region 11 (see FIG. 17), which will be formed to be connected to the capacitive element (not shown) as described later.

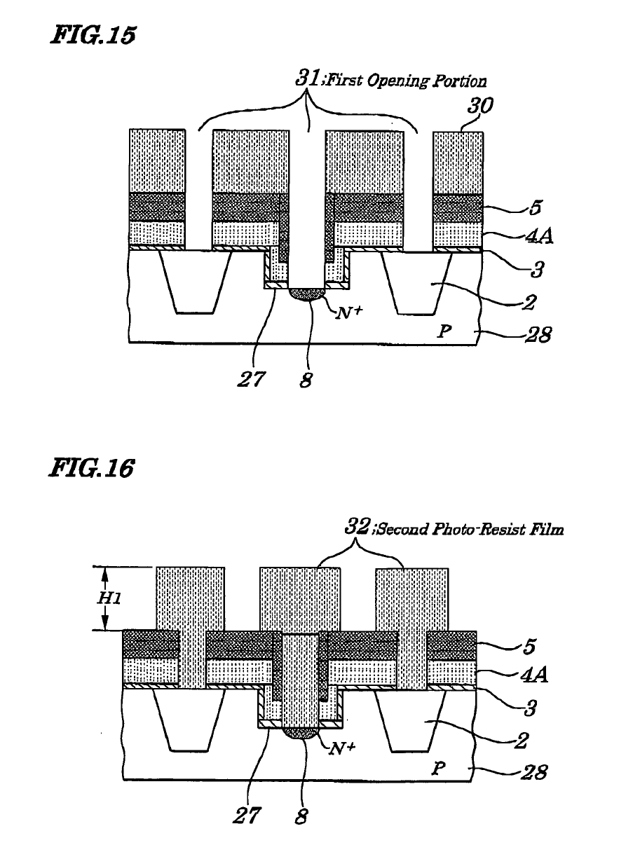

Next, after removing the first photo-resist film 30, as shown in FIG. 16 a photo-resist is applied on all surface, exposing and developing are carried out to form a second photo-resist film 32 having a desired pattern with the depth H1 to expose the desired regions of the first interlayer dielectric 5, in each of which a diffusion region is to be formed and to be connected to a capacitive contact (not shown) on a capacitive element side. In the embodiment, it is a feature that the second photo-resist film 32, which is used to form the diffusion region on the capacitive element side, is set to the depth Hi, the same as that of the first photo-resist film 30, which is used to form the diffusion region on the bit line side, as described above. Therefore, forming the first photo-resist film 30 and the second photo-resist film 32 to have same depth as each other avoids to remain the second photo-resist film 32 on a second opening portion 33 (a gate opening portion) (see FIG. 17) unlike in a conventional process shown in FIGS. 24A and 24B when the second opening portion 33 is formed after the second photo-resist film 32 as described later.

Next, as shown in FIG. 17, the first interlayer dielectric 5, the remaining gate conductive film 4A, and the gate insulating film 3 are selectively etched using the second photo-resist film 32 as a mask so as to form the second opening portions 33 (the gate opening portions) to expose the desired regions, in each of which the N-type diffusion region is to be formed and connected to the capacitive contact on the capacitive element side. This allows the remaining gate conductive film 4A patterned such that the gate electrode 4 is formed. Next, using the second photo-resist film 32 as a mask, the N-type impurity such as phosphorus (P), arsenic (As), or a like is injected into the P-type silicon semiconductor substrate 1 to have the dosage of 1×10¹²˜1×10¹⁴ ions/cm² through the second opening portion 33 and next the high concentration N-type diffusion 11 is formed by annealing. The high concentration N-type diffusion region 11 is formed in a manner to satisfy a relaxation of an electric field as a required condition of the capacitive element because the high concentration N-type diffusion region 11 serves as the diffusion region to be electrically connected to the capacitive contact (not shown), which is to be formed in a subsequent process. For this purpose, it is preferable to form the high concentration N-type diffusion region 11 to be relatively deep, at least to be deeper than the high concentration N-type diffusion region 8 which is formed to be connected to the bit line as described later. Furthermore when the high concentration N-type diffusion region 11 is formed, the second photo-resist film 32 is not remained on the second opening portion 33 as described above. As a result when the N-type impurity such as phosphorus (P), arsenic (As), or a like is injected into the P-type silicon semiconductor substrate 1 through the second opening portion 33 using the second photo-resist film 32 as a mask, only the second photo-resist film 32 acts as a mask so that the high concentration N-type diffusion region 11 is formed normally. Therefore the source region or the drain region is formed normally and then an increase in the yield can be obtained; because the difference in the threshold voltage Vt of the manufactured MOS-type transistor is suppressed.

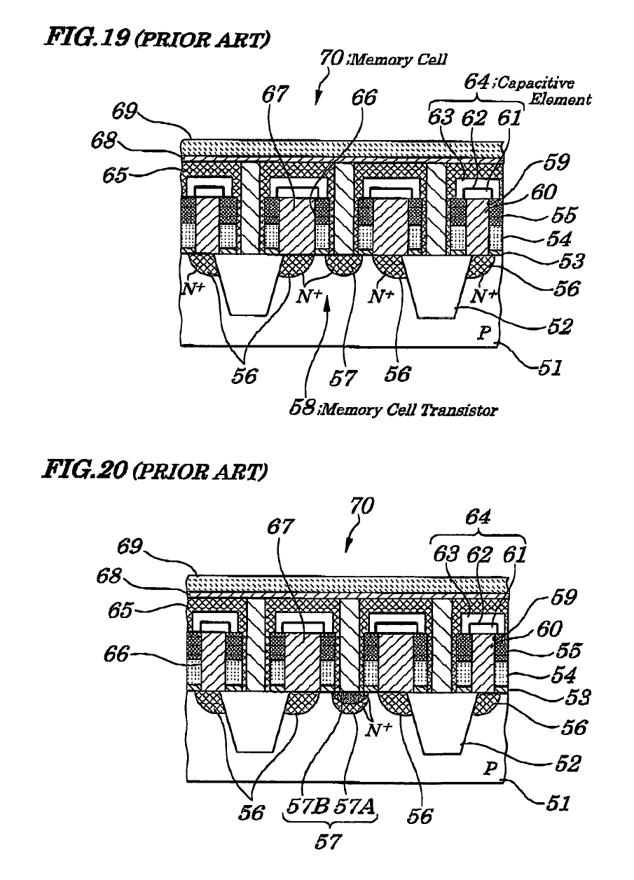

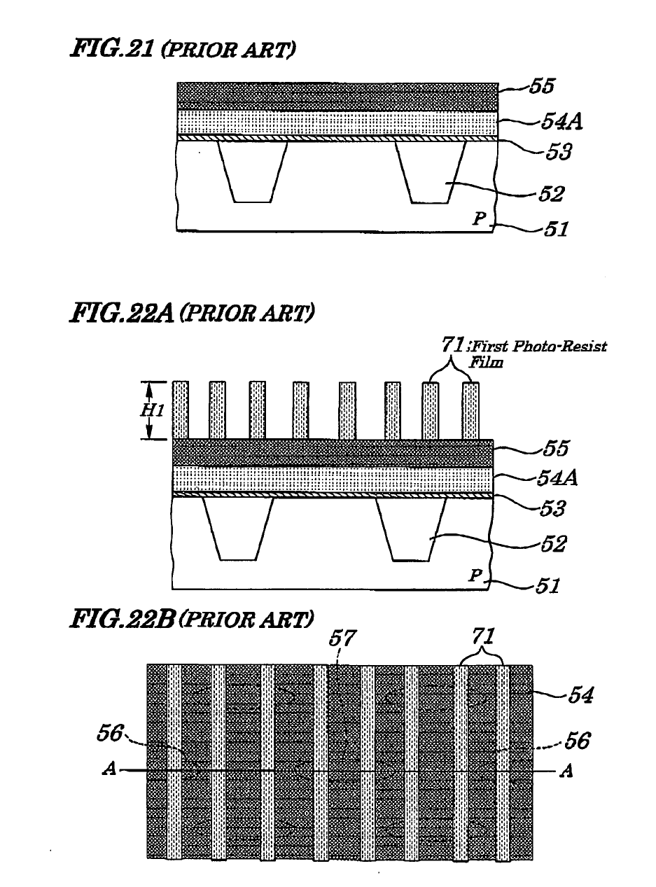

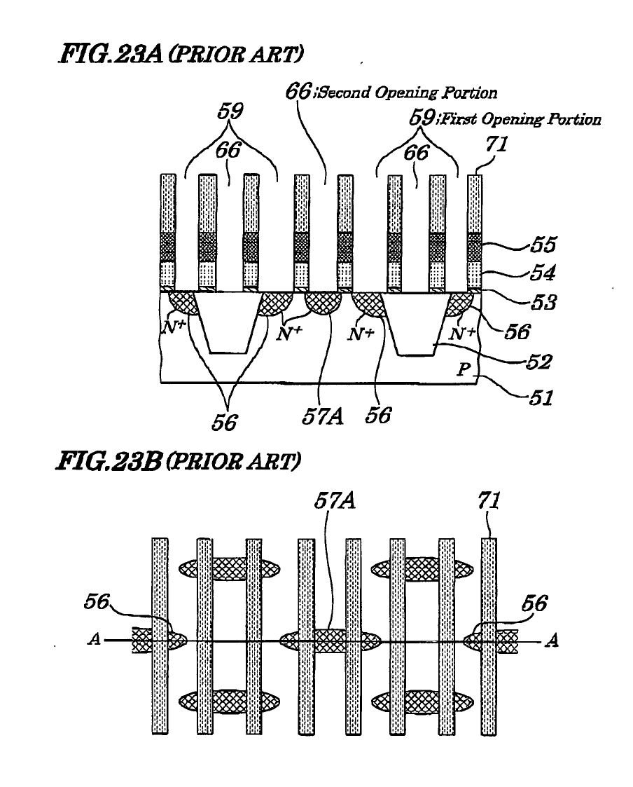

Next, as shown in FIG. 19, the second photo-resist film 32 is removed. The following processes are approximately repeated as described in the processes of the first embodiment shown in FIGS. 6A and 6E. As a result, a DRAM corresponding to FIG. 20 is completed. Therefore, the DRAM, formed by the method of the semiconductor device of the embodiment, has a channel (not shown), which is formed in a longitudinal direction adjacent to the gate insulating film 3 formed on a side face of the trench portion 27.

With the configurations above, a memory cell transistor is manufactured, by using the P-type silicon substrate 28, in which the trench portion 27 is formed in advance. And the memory cell is formed with the channel (not shown) in the longitudinal direction adjacent to the gate insulating film 3 formed on the side race of the trench portion 27. So that, compared with the methods described in the first embodiment and the second embodiment, a gate dimension variation due to an offset, which is easy to occur, can be avoided by performing a gate patterning on a region connected to the capacitive element and a region connected to the bit line for each.

Therefore, the third embodiment achieves approximately the same effect as the first embodiment and the second embodiment.

Additionally, with the configurations above, the gate dimension variation due to offset, which is easy to occur, can be suppressed by performing the gate patterning corresponding to the capacitive element as well as the bit line for each.

It is apparent that the present invention is not limited to the above embodiments but may be changed and modified without departing from the scope and spirit of the invention. For example, in each of the above embodiments, when the diffusion region connected to the capacitive element and the diffusion region connected to the bit line each are formed, the impurity is injected using the first photo-resist film and the second photo-resist film as the mask respectively. Though, when the impurity is injected, the first photo-resist film and the second photo-resist film are not necessary. That is, even in a case of removing the first photo-resist film and the second photo-resist film, if the gate electrode or a like is used as the mask, each of diffusion regions can be formed by a self-alignment method. A same dosage amount of the impurities, whose conductive type is opposite of each other, may be injected to ensure to form the diffusion regions. Also, a silicon dioxide is used as the gate Insulating film, the interlayer dielectric, and the protective insulation layer in each of the above embodiments, though not limited to the silicon dioxide; SiN (Silicon Nitride), BSG (Boron-Silicate Glass), PSG (Phospho-Silicate Glass), BPSG (Boron-Phospho-silicate Glass), or a like can be used for each dielectric. Furthermore, in principle, the drain region can serve as the source region, and the source region can serve as the drain region. Furthermore, each P-type semiconductor layer or each P-type semiconductor region can be exchanged for N-type semiconductor or N-type semiconductor region, respectively.

1. A method or manufacturing a semiconductor which comprises a first conductive-type of a semiconductor layer, a gate electrode formed through a gate insulating film on said semiconductor layer, a first semiconductor region being a second conductive-type and formed in said semiconductor layer at one side of said gate electrode, a capacitive element connected to the first semiconductor region, a second semiconductor region being the second conductive-type and formed in said semiconductor layer at another side of said gate electrode, a bit line connected to the second semiconductor region,
the method comprising a step or forming respectively said first semiconductor region and said second semiconductor region formed at a period of time during performing a gate electrode patterning process for patterning and forming said gate electrode,
wherein said gate electrode patterning process further comprises:
a first stage of said gate electrode patterning process forming said first semiconductor region together with a first stage of gate electrode pattern; and
a second stage of said gate electrode patterning process forming said second semiconductor region together with a first stage of gate electrode pattern.

2. The method of manufacturing a semiconductor according to claim 1, wherein said first stage of said gate electrode patterning process is followed by said second stage of said second gate electrode patterning process whereby said gate electrode is finally formed.

3. The method of manufacturing a semiconductor according to claim 1, wherein said second stage of said gate electrode patterning process is followed by said first stage of said second gate electrode patterning process whereby said gate electrode is finally formed.

4. The method of manufacturing a semiconductor according to claim 1, wherein said first semiconductor region is formed so as to be greater than said second semiconductor region in depth.

5. The method of manufacturing a semiconductor according to claim 1, wherein said second semiconductor region is formed so as to have higher impurity concentration than said first semiconductor region.

6. A method of manufacturing a semiconductor which comprises a first conductive-type of a semiconductor layer, a gate electrode formed through a gate insulating film on said semiconductor layer, a first semiconductor region being a second conductive-type and formed in said semiconductor layer at one side of said gate electrode, a capacitive element connected to the first semiconductor region, a second semiconductor region being the second conductive-type and formed in said semiconductor layer at another side of said gate electrode, a bit line connected to the second semiconductor region,
the method comprising steps of forming a trench in said semiconductor layer in such a manner that said trench is located at an approximately central position of a region where said bit line is to be formed; and then forming respectively said first semiconductor region and said second semiconductor region formed at a period of time during performing a gate electrode patterning process for patterning and forming said gate electrode,
wherein said gate electrode patterning process further comprises:
a first stage of said gate electrode patterning process forming said first semiconductor region together with a first stage of gate electrode pattern; and
a second stage of said gate electrode patterning process forming said second semiconductor region together with a first stage of gate electrode pattern.

7. The method of manufacturing a semiconductor according to claim 6, wherein said first stage of said gate electrode patterning process is followed by said second stage of said second gate electrode patterning process whereby said gate electrode is finally formed.

8. The method of manufacturing a semiconductor according to claim 6, wherein said second Stage of said gate electrode patterning process is followed by said first stage of said second gate electrode patterning process whereby said gate electrode is finally formed.

9. The method of manufacturing a semiconductor according to claim 6, wherein said first semiconductor region is formed so as to be greater than said second semiconductor region in depth.

10. The method of manufacturing a semiconductor according to claim 6, wherein said second semiconductor region is formed so as to have higher impurity concentration than said first semiconductor region.
